(19) United States
(12) Patent Application Publication
(10) Pub. No.: US 2025/0151253 A1
(43) Pub. Date: May 8, 2025

(54) MEMORY CELL STRUCTURES USING BACKSIDE METAL CROSS-COUPLE STRUCTURES

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/503,776

(22) Filed: Nov. 7, 2023

(51) Int. Cl. H10B 10/00; H01L 27/092; H01L 29/06; H01L 29/417; H01L 29/423; H01L 29/66; H01L 29/775; H01L 29/786

(52) U.S. Cl. CPC H10B 10/125; H10D 30/014; H10D 30/43; H10D 30/6729; H10D 30/6735; H10D 30/6757; H10D 62/121; H10D 84/85

(57) ABSTRACT

In an aspect, a semiconductor memory cell comprises a first inverter comprising a top field effect transistor (FET) and a bottom FET in a first complementary FET (CFET) structure having a first common gate as an input node of the first inverter, and a second inverter comprising a top FET and a bottom FET in a second complementary CFET structure having a second common gate as an input node of the second inverter. The first and second inverters are cross-coupled to each other using backside metal (BM) structures. The top and bottom FETs may be N-type and P-type, respectively, or vice-versa. The memory cell may include a passgate using top FETs of two additional CFET structures with bottom FETs disabled, or vice versa. The disabled FETs may be disabled during wafer process by suppressing growth of source/drain epitaxial regions and/or by removal of channels through etching and dielectric fill.

### BACKGROUND OF THE DISCLOSURE

### 1. Field of the Disclosure

This disclosure relates generally to semiconductor wafer process, and more specifically to compact memory cells using backside metal cross-couple structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or of parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor device comprising: a memory cell, comprising: a first inverter comprising a first top field effect transistor (FET) and a first bottom FET in a first complementary FET (CFET) structure having a first common gate as an input node of the first inverter; and a second inverter comprising a second top FET and a second bottom FET in a second complementary CFET structure having a second common gate as an input node of the second inverter, wherein an output node of the first inverter is coupled to the input node of the second inverter using a first backside metal (BM) structure and an output node of the second inverter is coupled to the input node of the first inverter using a second BM structure.

In an aspect, a method for providing a semiconductor device comprising a memory cell includes providing a first inverter comprising a first top FET and a first bottom FET in a first CFET structure having a first common gate as an input node of the first inverter; providing a second inverter comprising a second top FET and a second bottom FET in a second complementary CFET structure having a second common gate as an input node of the second inverter; providing a first BM structure that couples an output node of the first inverter to the input node of the second inverter; and providing a second BM structure that couples an output node of the second inverter to the input node of the first inverter.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 illustrates a nanosheet field effect transistor (FET).

FIG. 2 is a cross-sectional view of a semiconductor structure comprising a substrate upon which a pair of gate structures have been fabricated, according to aspects of the disclosure.

FIGS. 3A-3D are cross-sections of a semiconductor structure showing the structures that result from various techniques to disable one FET of a CFET stack, according to aspects of the disclosure.

FIG. 4A and FIG. 4B are simplified top views of a semiconductor structure of a compact memory cell using backside metal cross-coupling structures, according to aspects of the disclosure.

FIGS. 4C-4F are cross-sectional views of a semiconductor structure of a compact memory cell using backside metal cross-coupling structures, according to aspects of the disclosure.

FIG. 5A and FIG. 5B are simplified top views of a semiconductor structure of a compact memory cell using backside metal cross-coupling structures, according to aspects of the disclosure.

FIGS. 5C-5F are cross-sectional views of a semiconductor structure of a compact memory cell using backside metal cross-coupling structures, according to aspects of the disclosure.

FIG. 6 is a flowchart showing a portion of a simplified wafer process for fabricating a semiconductor structure of a compact memory cell using backside metal cross-coupling structures, according to aspects of the disclosure.

FIG. 7 is flowchart showing a method for fabricating a semiconductor device comprising a memory cell, according to aspects of the disclosure.

FIG. 8 illustrates a mobile device in accordance with some examples of the disclosure.

FIG. 9 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

In an aspect, a semiconductor memory cell comprises a first inverter comprising a top field effect transistor (FET) and a bottom FET in a first complementary FET (CFET) structure having a first common gate as an input node of the first inverter, and a second inverter comprising a top FET and a bottom FET in a second complementary CFET structure having a second common gate as an input node of the second inverter. The first and second inverters are cross-coupled to each other using backside metal (BM) structures. The top and bottom FETs may be N-type and P-type, respectively, or vice-versa. The memory cell may include a passgate using top FETs of two additional CFET structures with bottom FETs disabled, or vice versa. The disabled FETs may be disabled during wafer process by suppressing growth of source/drain epitaxial regions and/or by removal of channels through etching and dielectric fill.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to a semiconductor structure device and a manufacturing method of making the semiconductor structure device. Some aspects more specifically relate to compact memory cells using full backside connectivity to reduce cell area, reduce bitline resistance, reduce bitline capacitance, or combinations thereof.

Particular aspects of the subject matter described in this disclosure can be implemented to realize one or more of the following potential advantages. The use of backside metal to cross-connect a pair of CFET inverters enables a very compact memory cell layout. Moreover, by disabling an unused top FET or unused bottom FET of a CFET pair used for a passgate, e.g., by preventing growth of epitaxial source/drain regions on either side of the channel(s) of the unused FET, the memory cell layout can be made even more compact.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

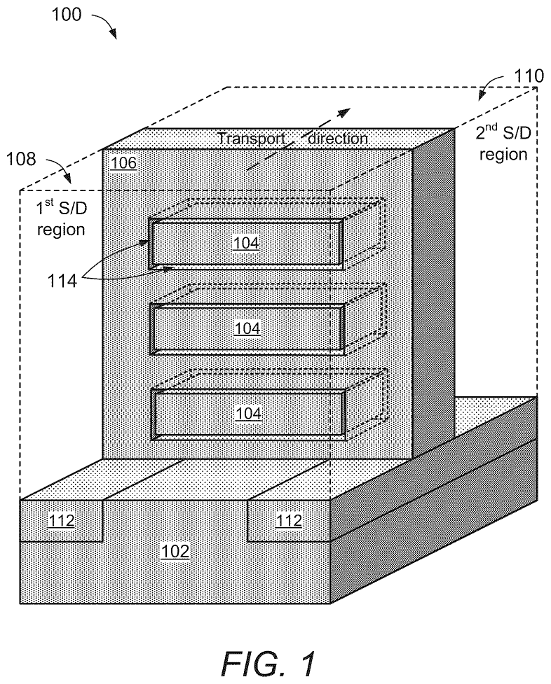

FIG. 1 illustrates a nanosheet field effect transistor (FET) 100. The nanosheet FET 100 shown in FIG. 1 is built upon a substrate 102 (e.g., silicon) and comprises a set of three nanosheets 104 that extend through a gate-all-around (GAA) structure 106. One end of the three nanosheets 104 are electrically connected together in a first, heavily-doped epitaxial (EPI) structure (not shown) to form a first source/drain (S/D) region 108, and the other end of the three nanosheets 104 are electrically connected together in a second, heavily-doped EPI structure (also not shown) to form a second S/D region 110. The gate structure is isolated from the substrate 102 by oxide isolation regions 112. The nanosheets 104 are the channels by which the charge carrier travels through the GAA structure 106 to get from the first S/D region 108 to the second S/D region 110, and thus may be referred to herein as “nanosheet channels”. The nanosheets 104 are electrically insulated from the GAA structure 106 by a dielectric layer 114 that surrounds the portions of the nanosheets 104 that go through the GAA structure 106.

For each pair of S/D regions on either side of a gate, one S/D region may operate as the source and the other S/D region may operate as the drain, or vice-versa. Generally, the term “source” is used to refer to the S/D region that is tied to the source of the charge carrier (i.e., for a PFET, the S/D region tied to VDD; for an NFET, the S/D region tied to VSS), and thus whether the first S/D region 108 or the second S/D region 110 is the source may depend on the specific electrical connection made to each.

The bottom and top surfaces of the substrate 102 in the orientation shown in FIG. 1 are commonly referred to as the “back” and “front” of the substrate. Thus, generally speaking, processes that create structures on the front of the substrate 102 (e.g., the GAA structure, channels, and S/D regions) are referred to as “frontside” processes, and processes that create structures on the back of the substrate 102 (or that create structures below the frontside structures, if the substrate 102 has been removed) are referred to as “backside” processes. Likewise, connections made during a frontside process are referred to as frontside connections, and connections made during a backside process are referred to as backside connections. The structure shown in FIG. 1 can be adapted so that the substrate 102 is removed entirely, to facilitate backside connectivity.

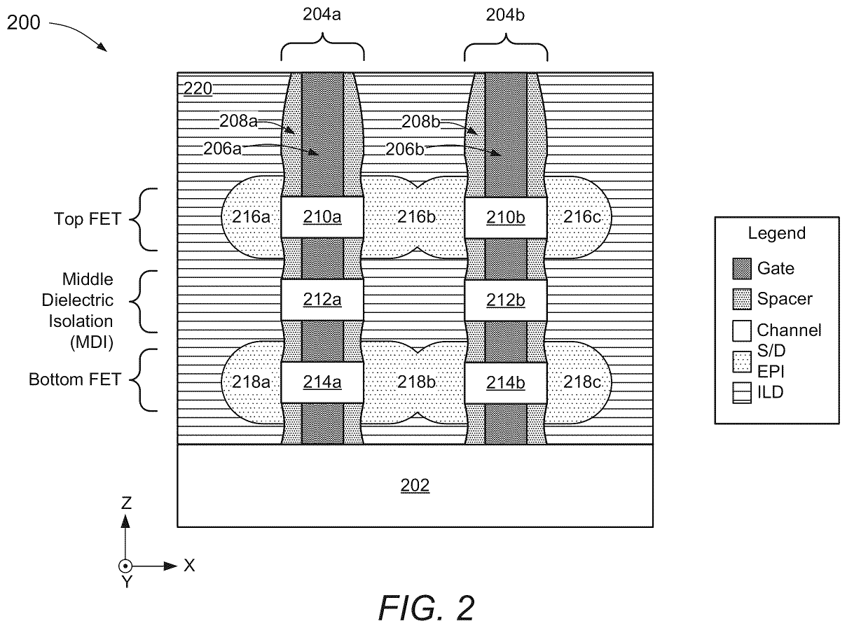

FIG. 2 is a cross-sectional view of semiconductor structure 200 comprising a substrate 202 upon which a pair of gate structures have been fabricated, according to aspects of the disclosure. The gate structures, which are labeled 204a and 204b, may be collectively referred to as gate structures 204 or individually referred to as gate structure 204a and gate structure 204b. The gate structures 204 extend in the Y direction and are spaced apart from each other in the X direction. The gate structure 204a comprises a metal gate structure 206a having spacers 208a one each side along the X direction, and a plurality of channels that extend through the metal gate structure 206a and the spacers 208a. In the example shown in FIG. 2, the top channel 210a is part of a top FET (TFET), the middle channel 212a is part of a middle dielectric isolation (MDI) structure, and the bottom channel 214a is part of a bottom FET (BFET). Likewise, the gate structure 204b comprises a metal gate structure 206b having spacers 208b one each side along the X direction, and a plurality of channels that extend through the metal gate structure 206b and the spacers 208b, where the top channel 210b is part of a top FET, the middle channel 212b is part of a middle dielectric isolation (MDI) structure, and the bottom channel 214b is part of a bottom FET.

In the example shown in FIG. 2, the semiconductor structure 200 includes a plurality of S/D EPI regions, including top S/D EPI regions labeled 216a through 216c and bottom S/D EPI regions labeled 218a through 218c. The top channel 210a provides a channel between the S/D EPI region 216a and the S/D EPI region 216b and the top channel 210b provides a channel between the S/D EPI region 216b and the S/D EPI region 216c. The bottom channel 214a provides a channel between the S/D EPI regions 218a and the S/D EPI region 218b, and the bottom channel 214b provides a channel between the S/D EPI region 218b and the S/D EPI region 218c. The channels that are part of the MDI structure, i.e., channel 212a and channel 212b, are not connected to any S/D EPI regions. In the example shown in FIG. 2, the gate structures 204 are surrounded by an electrically insulating inter-layer dielectric (ILD) 220.

It will be understood that the terms TFET and BFET refer to the top FET and bottom FET of a CFET pair, and that a phrase such as “TFET-type” means “a FET that is the same type as the TFET”, whatever that type is (e.g., an N-type or P-type). It will also be understood that semiconductor structure 200 may use P-type FETs (PFETs) as the top FETs and N-type FETs (NFETs) as the bottom FETs, or the reverse, depending on the specifics of the wafer process. It will also be understood that while FIG. 2 shows top FETs, bottom FETs, and MDI structures as having only one channel, in other embodiments each of these structures may a have more than one channel stacked vertically (i.e., in the Z direction) and separated from each other by gate and inner spacer structures. Using the semiconductor structure 200 as an example, each gate structure 204 contains a PFET and NFET pair stacked vertically, which constitutes a complementary FET (CFET) structure.

Since each gate structure 204 has a PFET/NFET pair, each gate structure 204 could implement an inverter logic. For example, presuming that the top FET is the PFET and the bottom FET is the NFET, gate structure 204a can implement an inverter by tying S/D EPI region 216a to VDD, tying S/D EPI region 218a to VSS, and tying S/D EPI region 216b to S/D EPI region 218b to be the output of the inverter, where the input of the inverter is tied to the metal gate structure 206a.

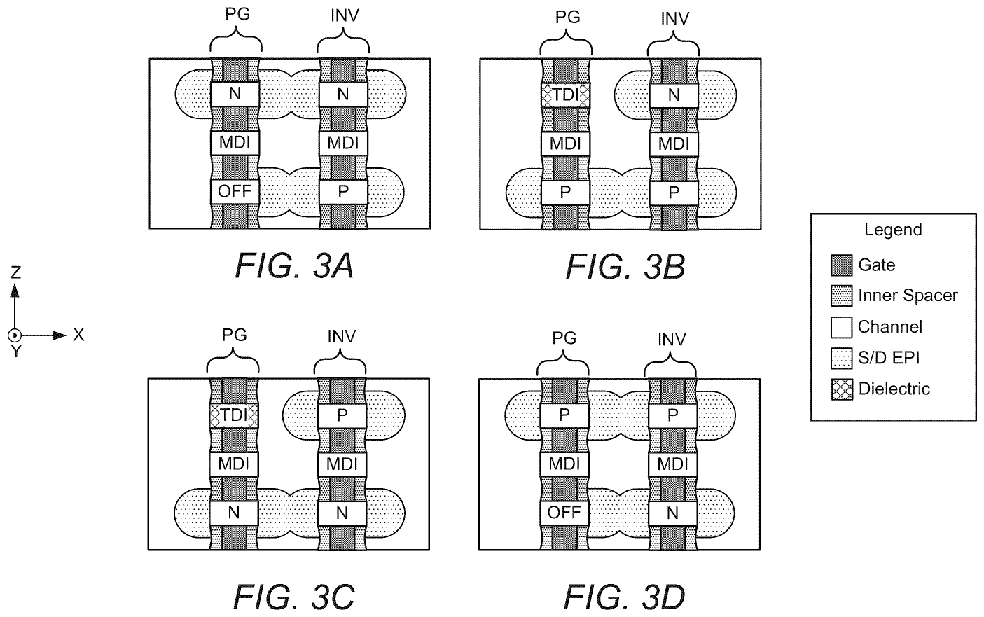

A static random access memory (SRAM) cell comprises a pair of cross-coupled inverters, where the output of one of the inverters connects to a bitline (BL) via a passgate (PG) that is controlled by a wordline (WL). Thus, a basic SRAM cell contains six transistors-namely a first PFET/NFET pair for one inverter, a second PFET/NFET pair for the other inverter, and either a PFET/PFET pair or an NFET/NFET pair for the passgate. A simple SRAM cell may be constructed using the CFET structures shown in FIG. 2, but since the FETs are in PFET/NFET pairs, this means that there will be four NFETs and four PFETs (two from each gate structure 204) and either two NFETs or two PFETs not used, depending on whether the passgate is a P-type or N-type. Thus, the circuit shown in FIG. 2 could be adapted to provide one inverter and one-half of the passgate, i.e., by disabling the unused PFET or NFET of the gate structure 204 that is used for the passgate structure. One way to disable the top or bottom FET is to omit the S/D EPI regions from either side of the channel(s) to be disabled. The resulting structure will vary, depending on whether the top FET is an NFET or a PFET, and on whether the passgate is an N-type of a P-type, as illustrated in FIGS. 3A through 3D.

FIG. 3A shows the resulting structure when the top FET is an NFET, the bottom FET is a PFET, and the passgate is a N-type. In this example, the bottom FET of the passgate has been disabled by preventing the growth of S/D EPI regions around the bottom channel.

FIG. 3B shows the resulting structure when the top FET is an NFET, the bottom FET is a PFET, and the passgate is a P-type. In this example, the top FET of the passgate has been disabled by preventing the growth of S/D EPI regions around the top channel and by etching away the channel and infilling with dielectric material to create a top dielectric isolation (TDI) structure, but in other implementations, prevention of S/D EPI growth alone or creating of the TDI alone may be performed.

FIG. 3C shows the resulting structure when the top FET is a PFET, the bottom FET is an NFET, and the passgate is a N-type. In this example, the top FET of the passgate has been disabled by preventing the growth of S/D EPI regions around the top channel and by etching away the channel and infilling with dielectric material to create a TDI structure.

FIG. 3D shows the resulting structure when the top FET is a PFET, the bottom FET is an NFET, and the passgate is a P-type. In this example, the bottom FET of the passgate has been disabled by preventing the growth of S/D EPI regions around the bottom channel.

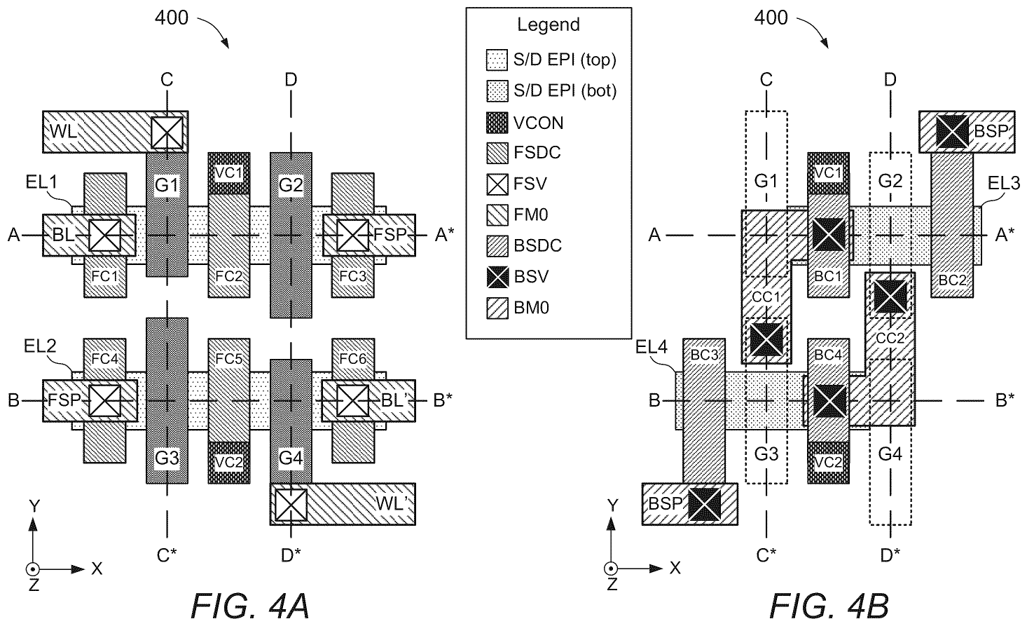

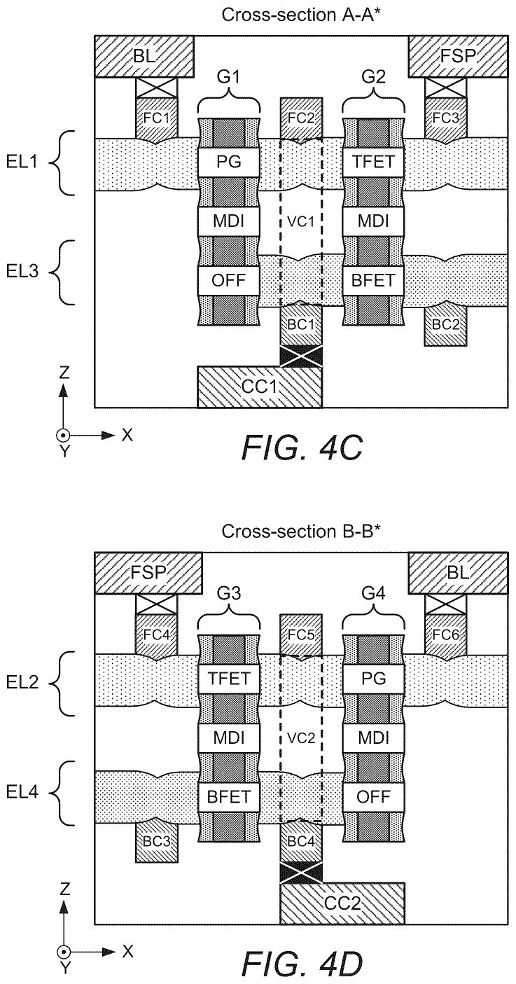

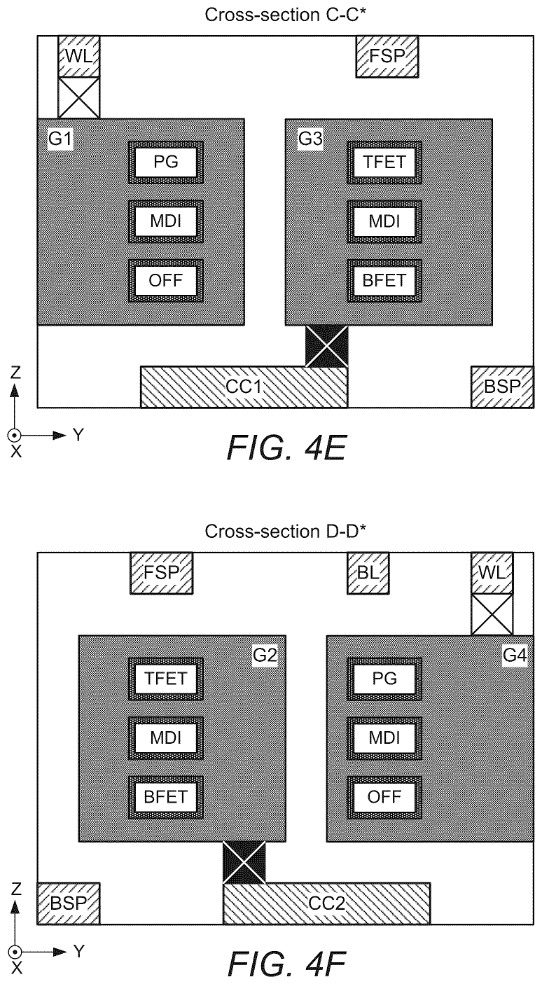

FIG. 4A and FIG. 4B are simplified top views of a semiconductor structure 400 of a compact CFET memory cell using backside metal cross-coupling structures, according to aspects of the disclosure. FIG. 4A shows the front side connections and FIG. 4B shows the back side connections. In particular, the elements shown in FIG. 4A may be above the elements shown in FIG. 4B in a vertical direction (e.g., the Z direction corresponding to a direction leaving the plane of the drawing sheet). In some aspects, FIG. 4A and FIG. 4B merely show some elements of the semiconductor structure 400 for illustration purposes, and other elements above and/or below the elements shown in FIGS. 4A-4B may be disposed but not shown in FIGS. 4A-4B.

In the example shown in FIGS. 4A-4B, the semiconductor structure 400 includes four gate structures, labeled G1, G2, G3, and G4, each comprising a CFET pair having a top FET (TFET) and a bottom FET (BFET). The TFETs of G1 and G2 have channels that connect different regions of a first EPI layer EL1, the TFETs of G3 and G4 have channels that connect different regions of a second EPI layer EL2, the BFETs of G1 and G2 have channels that connect different regions of a third EPI layer EL3, and the BFETs of G3 have channels that connect different regions of a fourth EPI layer EL4. In the example shown in FIGS. 4A-4B, the semiconductor structure 400 includes six frontside S/D contacts, labeled FC1, FC2, FC3, FC4, FC5, and FC6. In the example shown in FIGS. 4A-4B, the semiconductor structure 400 includes four backside S/D contacts, labeled BC1, BC2, BC3, and BC4. In the example shown in FIGS. 4A-4B, the semiconductor structure 400 includes two cross-connect structures, labeled CC1 and CC2. G2 and G3 are the cross-coupled inverters. In the example shown in FIGS. 4A-4B, the semiconductor structure 400 includes two vertical connectors (VCs), labeled VC1 and VC2. Each VC extends in the Z direction and electrically connects a S/D region of a TFET to a S/D region of a BFET in a CFET pair, e.g., by electrically connecting an FC to a BC below it.

The TFET of G2 is connected to a frontside power supply (FSP) via FC3, and the BFET of G2 is connected to backside power supply (BSP) via BC2. In some aspects, the TFETs are NFETs, the BFETs are PFETs, the FSP is VSS, and the BSP is VDD. In other aspects, the TFETs are PFETs, the BFETs are NFETs, the FSP is VDD, and the BSP is VSS. In the example shown in FIGS. 4A-4B, the pass gates are constructed from TFETs, and the BFETs are disabled.

The outputs of the TFET and BFET of G2 are connected together by FC2, VC1, and BC1, and that output is connected to the gate of G3 via CC1. The TFET of G3 is connected to FSP via FC4, and the BFET of G3 is connected to BSP via BC3. The outputs of the TFET and BFET of G3 are connected together by FC5, VC2, and BC4, and that output is connected to the gate of G2 via CC2. The top half of G1 is a passgate, controlled by wordline WL, to connect the output of the inverter formed by G2 to the first bitline BL, and bottom half of G1 has been disabled. The top half of G4 is a passgate, controlled by WL, to connect the output of the inverter formed by G3 to the second bitline BL′, and the bottom half of G4 has been disabled. The cross-sections A-A*, B-B*, C-C*, and D-D*, with locations indicated in FIGS. 4A-4B, are shown in more detail in FIGS. 4C-4F.

FIG. 4C is a cross-sectional view of the semiconductor structure 400 through cross-section A-A*, according to aspects of the disclosure. As shown in FIG. 4C, the top EPI layer EL1 exists on either side of the TFET of G1, which operates as a TFET-type passgate and is thus labeled “PG” in FIG. 4C, but the bottom EPI layer EL3 is not present around the BFET of G1, which disables the BFET of G1, which is thus labeled “OFF” in FIG. 4C. The output of the TFET and BFET transistors of G2 is tied together by FC2, VC1 (which is out of the plane of cross-section A-A* and thus shown with a dashed outline), and BC1. The output of the first inverter formed by the TFET and BFET of G2 is routed to the gate of the second inverter via BC1 and CC1.

FIG. 4D is a cross-sectional view of the semiconductor structure 400 through cross-section B-B*, according to aspects of the disclosure. As shown in FIG. 4D, the top EPI layer EL2 exists on either side of the TFET of G4, which operates an N-type passgate and is thus labeled “PG” in FIG. 4D, but the bottom EPI layer EL4 is not present around the BFET of G4, which disables the BFET of G4, which is thus labeled “OFF” in FIG. 4D. The output of the TFET and BFET transistors of G3 is tied together by FC5, VC2 (which is out of the plane of cross-section B-B* and thus shown with a dashed outline), and BC4. The output of the second inverter formed by the TFET and BFET of G3 is routed to the gate of the first inverter via BC4 and CC2.

FIG. 4E is a cross-sectional view of the semiconductor structure 400 through cross-section C-C*, according to aspects of the disclosure. FIG. 4E shows the cross-sections of G1 and G3, and shows how the backside connector CC1 connects to the backside of G3.

FIG. 4F is a cross-sectional view of the semiconductor structure 400 through cross-section D-D*, according to aspects of the disclosure. FIG. 4F shows the cross-sections of G2 and G4, and shows how the backside connector CC2 connects to the backside of G2.

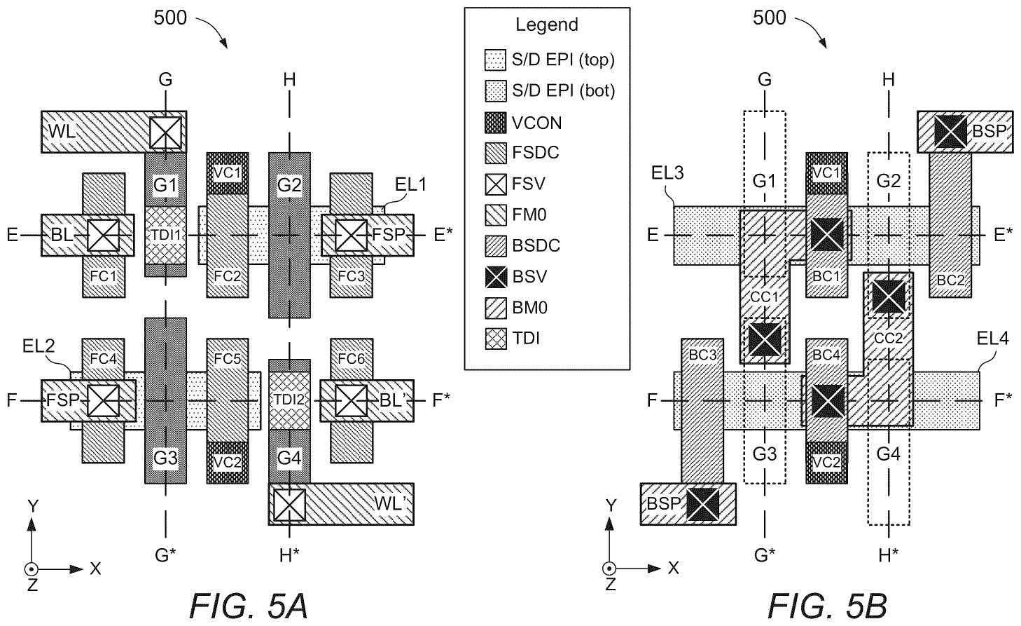

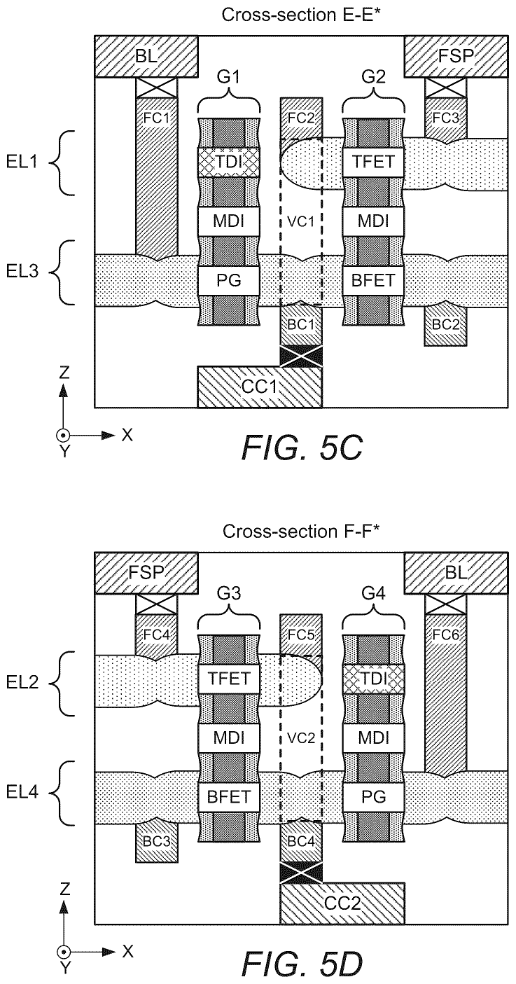

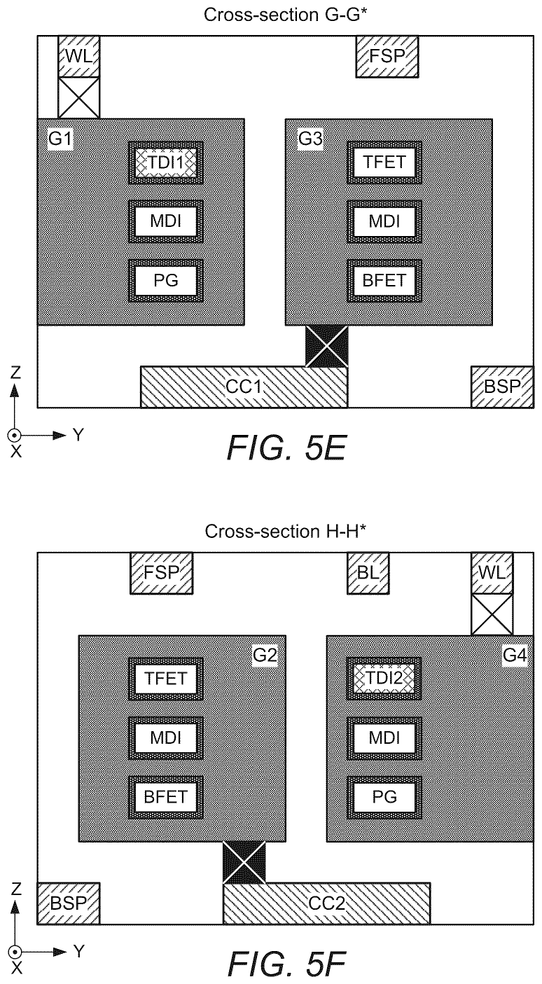

FIG. 5A and FIG. 5B are simplified top views of a semiconductor structure 500 of a compact CFET memory cell using backside metal cross-coupling structures, according to aspects of the disclosure. FIG. 5A shows the front side connections and FIG. 5B shows the back side connections. In particular, the elements shown in FIG. 5A may be above the elements shown in FIG. 5B in a vertical direction (e.g., the Z direction corresponding to a direction leaving the plane of the drawing sheet). In some aspects, FIG. 5A and FIG. 5B merely show some elements of the semiconductor structure 500 for illustration purposes, and other elements above and/or below the elements shown in FIGS. 5A-5B may be disposed but not shown in FIGS. 5A-5B.

In the example shown in FIGS. 5A-5B, the semiconductor structure 500 has a similar topology as the semiconductor structure 400 and therefore the description of like-named structures G1-G4, FC1-FC6, BC1-BC4, CC1-CC2, VC1-VC2, FSP, and BSP will not be repeated here. However, the semiconductor structure 500 differs from the semiconductor structure 400 in that, in the semiconductor structure 500, the pass gates are constructed from BFETs, and the TFETs are disabled. As a result, the dimensions and locations of the EPI layers EL1-EL4 in the semiconductor structure 500 differ from the dimensions and locations of the like-named EPI layers EL1-EL4 in the semiconductor structure 400, and there are two TDI regions, TDI1 within G1, and TDI2 within G4. These differences are more easily seen in the cross-sections E-E*, F-F*, G-G*, and H-H*, shown in FIGS. 5C-5F, respectively.

FIG. 5C is a cross-sectional view of the semiconductor structure 500 through cross-section E-E*, according to aspects of the disclosure. As shown in FIG. 5C, the bottom EPI layer EL3 exists on either side of the BFET of G1, which operates as a BFET-type passgate and is thus labeled “PG” in FIG. 5C, but the top EPI layer EL1 is not present around the TFET of G1, which has been replaced by TDI1 in FIG. 5C. The output of the TFET and BFET transistors of G2 is tied together by FC2, VC1 (which is out of the plane of cross-section E-E* and thus shown with a dashed outline), and BC1. The output of the first inverter formed by the TFET and BFET of G2 is routed to the gate of the second inverter via BC1 and CC1.

FIG. 5D is a cross-sectional view of the semiconductor structure 500 through cross-section F-F*, according to aspects of the disclosure. As shown in FIG. 5D, the bottom EPI layer EL4 exists on either side of the BFET of G4, which operates an BFET-type passgate and is thus labeled “PG” in FIG. 5D, but the top EPI layer EL4 is not present around the TFET of G4, which has been replaced by TDI2 in FIG. 5D. The output of the TFET and BFET transistors of G3 is tied together by FC5, VC2 (which is out of the plane of cross-section F-F* and thus shown with a dashed outline), and BC4. The output of the second inverter formed by the TFET and BFET of G3 is routed to the gate of the first inverter via BC4 and CC2.

FIG. 5E is a cross-sectional view of the semiconductor structure 500 through cross-section G-G*, according to aspects of the disclosure. FIG. 5E shows the cross-sections of G1 (showing TDI1) and G3 and shows how the backside connector CC1 connects to the backside of G3.

FIG. 5F is a cross-sectional view of the semiconductor structure 500 through cross-section H-H*, according to aspects of the disclosure. FIG. 5F shows the cross-sections of G2 and G4 (showing TDI2) and shows how the backside connector CC2 connects to the backside of G2.

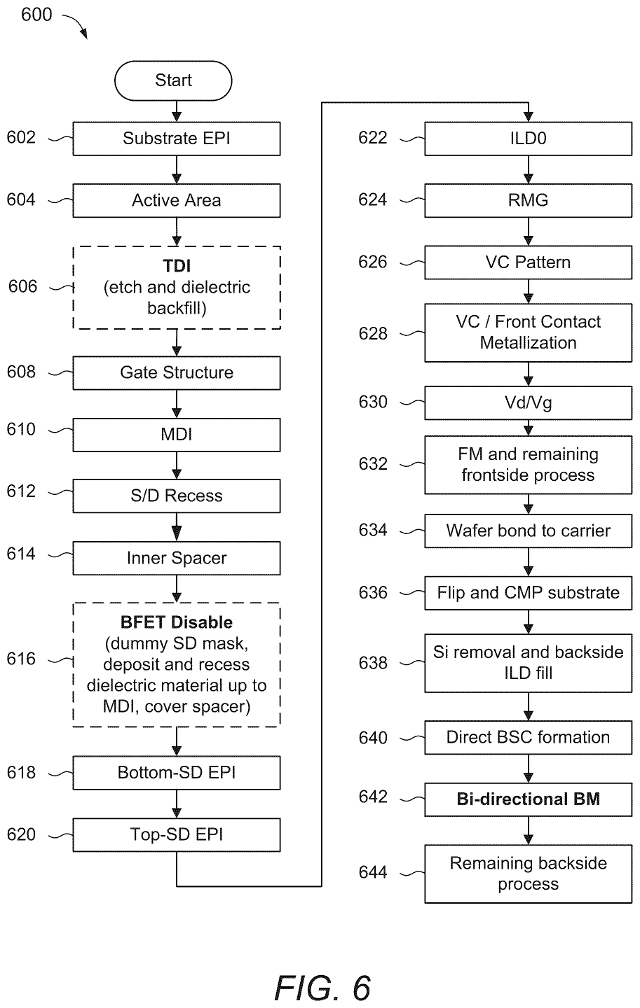

FIG. 6 is a flowchart showing a portion of a simplified wafer process for fabricating the structures shown in FIGS. 4A-4F and FIGS. 5A-5F, according to aspects of the disclosure. As shown in FIG. 6, the process 600 may include, at block 602, forming the substrate EPI, e.g., the substrate 202 shown in FIG. 2. The process 600 may include, at block 604, forming the active area.

The process 600 may optionally include, at block 606, a TDI process. In some aspects, forming a TDI includes removing the top FET channel, e.g., by an etch step, backfilling the resulting cavity with a dielectric, and an optional planarization step such as chemical/mechanical polishing (CMP). In some aspects, this optional step is performed when the memory cell topology uses a BFET-type passgate and thus the TFET is disabled or removed from the gate that forms the passgate, such as is shown in FIGS. 5A-5F.

The process 600 may include, at block 608, forming the gate structure(s), e.g., G1-G4 in FIGS. 4A-5F. The process 600 may include, at block 610, forming the MDI, e.g., the MDI regions in FIGS. 4A-5F. The process 600 may include, at block 612, forming the S/D recess, e.g., forming the volumes to the left and right of gate structures G1-G4 in FIGS. 4A-5F. The process 600 may include, at block 614, forming the inner spacer, e.g., the spacers 208a and 208b in FIG. 2.

The process 600 may optionally include, at block 616, a BFET disable process. In some aspects, disabling a BFET includes using a dummy SD mask to prevent formation of bottom EPI structures, depositing dielectric material up to the MDI, and forming a cover spacer. In some aspects, this optional step is performed when the memory cell topology uses a TFET-type passgate and thus the BFET is disabled or removed from the gate that forms the passgate, such as is shown in FIGS. 4A-4F.

The process 600 may include, at block 618, forming the bottom S/D EPI structure, e.g., the bottom EPI layers EL3 and EL4 in FIGS. 4A-5F. The process 600 may include, at block 620, forming the top S/D EPI structure, e.g., the top EPI layers EL1 and EL2 in FIGS. 4A-5F. The process 600 may include, at block 622, depositing the zero-layer ILD (ILDO), e.g., the ILD 220 in FIG. 2. The process 600 may include, at block 624, forming the replacement metal gate (RMG) structures. The process 600 may include, at block 626, patterning and etching to form a vertical connector (VC), e.g., VC1 and VC2 in FIGS. 4A-5F, which may be referred to as “VC patterning.” The process 600 may include, at block 628, VC and front contact metallization. The process 600 may include, at block 630, forming frontside vias (FSVs), which may be S/D vias (Vd) and/or gate vias (Vg). The process 600 may include, at block 632, forming frontside metal (FM) structures and performing the remaining frontside process steps. In some aspects, the FM structures may comprise frontside metal-zero (FM0) structures, but other metal levels may be additionally or alternatively used.

The process 600 may include, at block 634, bonding the wafer to a carrier. The process 600 may include, at block 636, flipping the wafer and removing the substrate via a CMP process. The process 600 may include, at block 638, a silicon removal and backside ILD fill process. The process 600 may include, at block 640, forming direct backside contacts (BSCs), e.g., the BC1-BC4 in FIGS. 4A-5F. The process 600 may include, at block 642, forming a bidirectional cross-connect using backside metal (BM), e.g., CC1 and CC2 in FIGS. 4A-5F. In some aspects, CC1 and CC2 may comprise backside metal-zero (BM0) structures, but other metal levels may be additionally or alternatively used. The remaining process steps are then performed, shown as block 644.

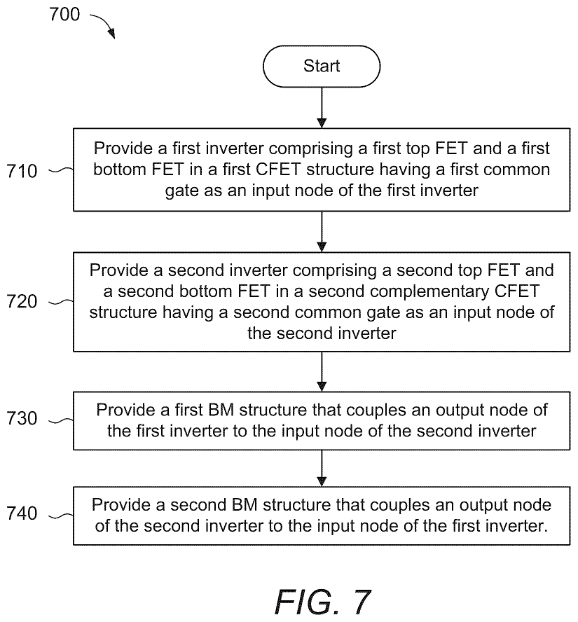

FIG. 7 is a flowchart of an example process 700 associated with memory cell structures using backside metal cross-couple structures, according to aspects of the disclosure. As shown in FIG. 7, process 700 may include, at block 710, providing a first inverter comprising a first top FET and a first bottom FET in a first CFET structure having a first common gate as an input node of the first inverter, e.g., an inverter comprising the top and bottom FETs of G2 in FIG. 4A.

As further shown in FIG. 7, process 700 may include, at block 720, providing a second inverter comprising a second top FET and a second bottom FET in a second complementary CFET structure having a second common gate as an input node of the second inverter, e.g., an inverter comprising the top and bottom FETs of G3 in FIG. 4A.

As further shown in FIG. 7, process 700 may include, at block 730, providing a first backside metal (BM) structure that couples an output node of the first inverter to the input node of the second inverter, e.g., CC1 in FIG. 4B.

As further shown in FIG. 7, process 700 may include, at block 740, providing a second BM structure that couples an output node of the second inverter to the input node of the first inverter, e.g., CC2 in FIG. 4B.

In some aspects, the output node of the first inverter comprises a first vertical connector that electrically couples a source/drain (S/D) region of the first top FET to an S/D region of the first bottom FET (e.g., VC1 in FIG. 4A) and the output node of the second inverter comprises a second vertical connector that electrically couples a S/D region of the second top FET to an S/D region of the second bottom FET (e.g., VC2 in FIG. 4A).

In some aspects, process 700 includes providing a passgate comprising a third top FET in a third CFET structure (e.g., G1 in FIG. 4A) and a fourth top FET in a fourth CFET structure (e.g., G4 in FIG. 4A).

In some aspects, process 700 includes removing each of a third bottom FET in the third CFET structure and a fourth bottom FET in the fourth CFET structure.

In some aspects, each of a third bottom FET in the third CFET structure and a fourth bottom FET in the fourth CFET structure is incomplete and non-functional (e.g., by preventing the growth of EL3 on either side of G1 in FIG. 4B and preventing the growth of EL4 on either side of G3 in FIG. 4B).

In some aspects, process 700 includes providing a passgate comprising a third bottom FET in a third CFET structure (e.g., G1 in FIG. 5A) and a fourth bottom FET in a fourth CFET structure (e.g., G4 in FIG. 5A).

In some aspects, process 700 includes removing each of a third top FET in the third CFET structure and a fourth top FET in the fourth CFET structure, e.g., creating TDI1 and TDI2 in FIG. 5A.

In some aspects, each of a third top FET in the third CFET structure and a fourth top FET in the fourth CFET structure is incomplete and non-functional (e.g., by preventing the growth of EL1 on either side of G1 in FIG. 5A and preventing the growth of EL2 on either side of G4 in FIG. 5A).

In some aspects, the top FETs comprise N-type FETs and the bottom FETs comprise P-type FETs. In these aspects, FSP may be VSS and BSP may be VDD.

In some aspects, the top FETs comprise P-type FETs and the bottom FETs comprise N-type FETs. In these aspects, FSP may be VDD and BSP may be VSS.

Process 700 may include additional implementations, such as any single implementation or any combination of implementations described below and/or in connection with one or more other processes described elsewhere herein. Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

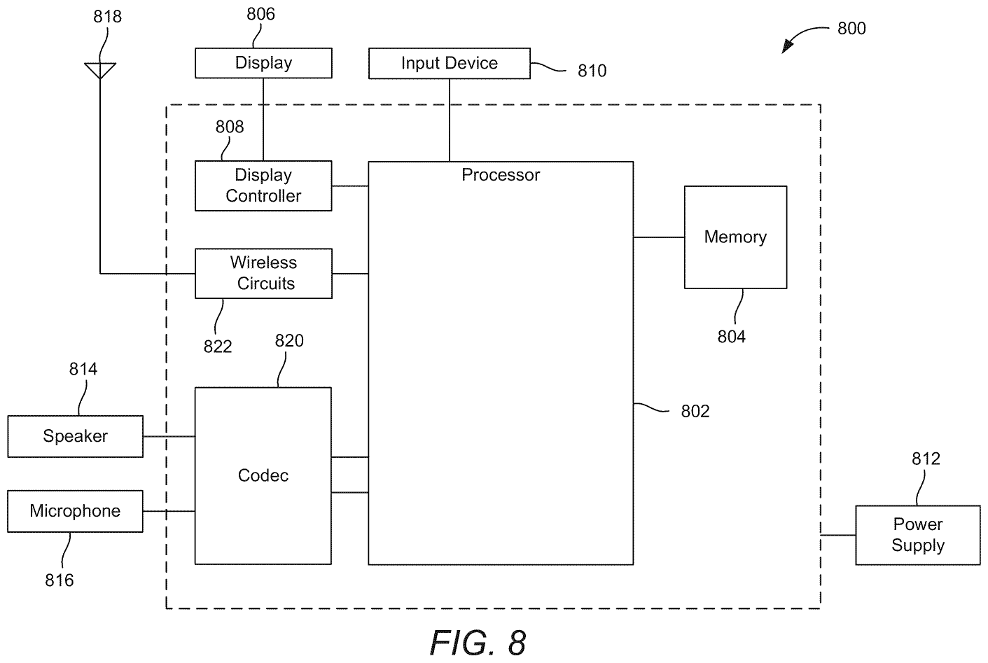

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

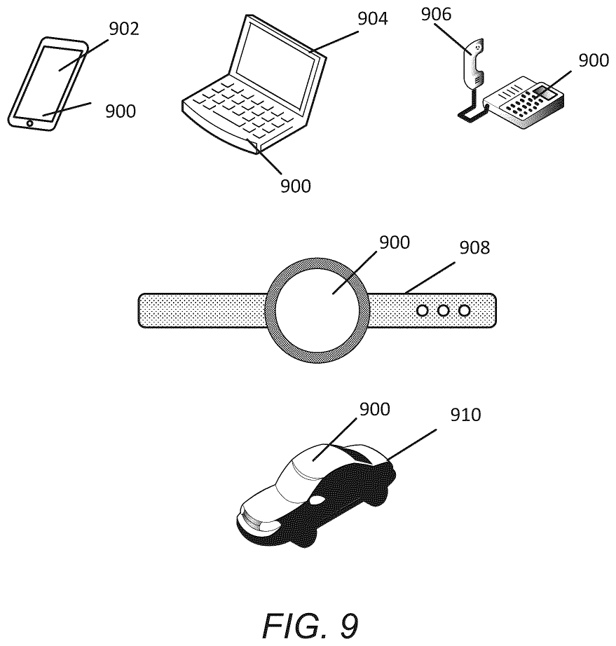

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 902, a laptop computer device 904, a fixed location terminal device 906, a wearable device 908, or automotive vehicle 910 may include a semiconductor device 900 (which may include semiconductor structures 400 and 500) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. A semiconductor device comprising: a memory cell, comprising: a first inverter comprising a first top field effect transistor (FET) and a first bottom FET in a first complementary FET (CFET) structure having a first common gate as an input node of the first inverter; and a second inverter comprising a second top FET and a second bottom FET in a second complementary CFET structure having a second common gate as an input node of the second inverter, wherein an output node of the first inverter is coupled to the input node of the second inverter using a first backside metal (BM) structure and an output node of the second inverter is coupled to the input node of the first inverter using a second BM structure.
Clause 2. The semiconductor device of clause 1, wherein the output node of the first inverter comprises a first vertical connector that electrically couples a source/drain (S/D) region of the first top FET to an S/D region of the first bottom FET and the output node of the second inverter comprises a second vertical connector that electrically couples an S/D region of the second top FET to an S/D region of the second bottom FET.
Clause 3. The semiconductor device of any of clauses 1 to 2, wherein the memory cell further comprises a passgate comprising a third top FET in a third CFET structure and a fourth top FET in a fourth CFET structure.
Clause 4. The semiconductor device of clause 3, wherein each of a third bottom FET in the third CFET structure and a fourth bottom FET in the fourth CFET structure is removed.
Clause 5. The semiconductor device of any of clauses 3 to 4, wherein each of a third bottom FET in the third CFET structure and a fourth bottom FET in the fourth CFET structure is incomplete and/or non-functional.
Clause 6. The semiconductor device of any of clauses 1 to 5, wherein the memory cell further comprises a passgate comprising a third bottom FET in a third CFET structure and a fourth bottom FET in a fourth CFET structure.
Clause 7. The semiconductor device of clause 6, wherein each of a third top FET in the third CFET structure and a fourth top FET in the fourth CFET structure is removed.
Clause 8. The semiconductor device of any of clauses 6 to 7, wherein each of a third top FET in the third CFET structure and a fourth top FET in the fourth CFET structure is incomplete and/or non-functional.
Clause 9. The semiconductor device of any of clauses 1 to 8, wherein each of the first top FET and the second top FET comprises an N-type FET and wherein each of the first bottom FET and the second bottom FET comprises a P-type FET.
Clause 10. The semiconductor device of any of clauses 1 to 9, wherein each of the first top FET and the second top FET comprises a P-type FET and wherein each of the first bottom FET and the second bottom FET comprises an N-type FET.
Clause 11. The semiconductor device of any of clauses 1 to 10, wherein at least one of the first BM structure and the second BM structure comprise backside metal layer zero (BM0).
Clause 12. The semiconductor device of any of clauses 1 to 11, wherein the semiconductor device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
Clause 13. A method for fabricating a semiconductor device comprising a memory cell, the method comprising: providing a first inverter comprising a first top field effect transistor (FET) and a first bottom FET in a first complementary FET (CFET) structure having a first common gate as an input node of the first inverter; providing a second inverter comprising a second top FET and a second bottom FET in a second complementary CFET structure having a second common gate as an input node of the second inverter; providing a first backside metal (BM) structure that couples an output node of the first inverter to the input node of the second inverter; and providing a second BM structure that couples an output node of the second inverter to the input node of the first inverter.
Clause 14. The method of clause 13, wherein the output node of the first inverter comprises a first vertical connector that electrically couples a source/drain (S/D) region of the first top FET to an S/D region of the first bottom FET and the output node of the second inverter comprises a second vertical connector that electrically couples an S/D region of the second top FET to an S/D region of the second bottom FET.
Clause 15. The method of any of clauses 13 to 14, further comprising providing a passgate comprising a third top FET in a third CFET structure and a fourth top FET in a fourth CFET structure.
Clause 16. The method of clause 15, further comprising removing each of a third bottom FET in the third CFET structure and a fourth bottom FET in the fourth CFET structure.
Clause 17. The method of any of clauses 15 to 16, wherein each of a third bottom FET in the third CFET structure and a fourth bottom FET in the fourth CFET structure is incomplete and/or non-functional.
Clause 18. The method of any of clauses 13 to 17, further comprising providing a passgate comprising a third bottom FET in a third CFET structure and a fourth bottom FET in a fourth CFET structure.
Clause 19. The method of clause 18, further comprising removing each of a third top FET in the third CFET structure and a fourth top FET in the fourth CFET structure.
Clause 20. The method of any of clauses 18 to 19, wherein each of a third top FET in the third CFET structure and a fourth top FET in the fourth CFET structure is incomplete and/or non-functional.
Clause 21. The method of any of clauses 13 to 20, wherein each of the first top FET and the second top FET comprises an N-type FET and wherein each of the first bottom FET and the second bottom FET comprises a P-type FET.
Clause 22. The method of any of clauses 13 to 21, wherein each of the first top FET and the second top FET comprises a P-type FET and wherein each of the first bottom FET and the second bottom FET comprises an N-type FET.
Clause 23. The method of any of clauses 13 to 22, wherein at least one of the first BM structure and the second BM structure comprise backside metal layer zero (BM0).
Clause 24. The method of any of clauses 13 to 23, further comprising incorporating the semiconductor device into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor device comprising:
a memory cell, comprising:
a first inverter comprising a first top field effect transistor (FET) and a first bottom FET in a first complementary FET (CFET) structure having a first common gate as an input node of the first inverter; and
a second inverter comprising a second top FET and a second bottom FET in a second complementary CFET structure having a second common gate as an input node of the second inverter,
wherein an output node of the first inverter is coupled to the input node of the second inverter using a first backside metal (BM) structure and an output node of the second inverter is coupled to the input node of the first inverter using a second BM structure.

2. The semiconductor device of claim 1, wherein the output node of the first inverter comprises a first vertical connector that electrically couples a source/drain (S/D) region of the first top FET to an S/D region of the first bottom FET and the output node of the second inverter comprises a second vertical connector that electrically couples an S/D region of the second top FET to an S/D region of the second bottom FET.

3. The semiconductor device of claim 1, wherein the memory cell further comprises a passgate comprising a third top FET in a third CFET structure and a fourth top FET in a fourth CFET structure.

4. The semiconductor device of claim 3, wherein each of a third bottom FET in the third CFET structure and a fourth bottom FET in the fourth CFET structure is removed.

5. The semiconductor device of claim 3, wherein each of a third bottom FET in the third CFET structure and a fourth bottom FET in the fourth CFET structure is incomplete and/or non-functional.

6. The semiconductor device of claim 1, wherein the memory cell further comprises a passgate comprising a third bottom FET in a third CFET structure and a fourth bottom FET in a fourth CFET structure.

7. The semiconductor device of claim 6, wherein each of a third top FET in the third CFET structure and a fourth top FET in the fourth CFET structure is removed.

8. The semiconductor device of claim 6, wherein each of a third top FET in the third CFET structure and a fourth top FET in the fourth CFET structure is incomplete and/or non-functional.

9. The semiconductor device of claim 1, wherein each of the first top FET and the second top FET comprises an N-type FET and wherein each of the first bottom FET and the second bottom FET comprises a P-type FET.

10. The semiconductor device of claim 1, wherein each of the first top FET and the second top FET comprises a P-type FET and wherein each of the first bottom FET and the second bottom FET comprises an N-type FET.

11. The semiconductor device of claim 1, wherein at least one of the first BM structure and the second BM structure comprise backside metal layer zero (BM0).

12. The semiconductor device of claim 1, wherein the semiconductor device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

13. A method for fabricating a semiconductor device comprising a memory cell, the method comprising:
providing a first inverter comprising a first top field effect transistor (FET) and a first bottom FET in a first complementary FET (CFET) structure having a first common gate as an input node of the first inverter;
providing a second inverter comprising a second top FET and a second bottom FET in a second complementary CFET structure having a second common gate as an input node of the second inverter;
providing a first backside metal (BM) structure that couples an output node of the first inverter to the input node of the second inverter; and
providing a second BM structure that couples an output node of the second inverter to the input node of the first inverter.

14. The method of claim 13, wherein the output node of the first inverter comprises a first vertical connector that electrically couples a source/drain (S/D) region of the first top FET to an S/D region of the first bottom FET and the output node of the second inverter comprises a second vertical connector that electrically couples an S/D region of the second top FET to an S/D region of the second bottom FET.

15. The method of claim 13, further comprising providing a passgate comprising a third top FET in a third CFET structure and a fourth top FET in a fourth CFET structure.

16. The method of claim 15, further comprising removing each of a third bottom FET in the third CFET structure and a fourth bottom FET in the fourth CFET structure.

17. The method of claim 15, wherein each of a third bottom FET in the third CFET structure and a fourth bottom FET in the fourth CFET structure is incomplete and/or non-functional.

18. The method of claim 13, further comprising providing a passgate comprising a third bottom FET in a third CFET structure and a fourth bottom FET in a fourth CFET structure.

19. The method of claim 18, further comprising removing each of a third top FET in the third CFET structure and a fourth top FET in the fourth CFET structure.

20. The method of claim 18, wherein each of a third top FET in the third CFET structure and a fourth top FET in the fourth CFET structure is incomplete and/or non-functional.

21. The method of claim 13, wherein each of the first top FET and the second top FET comprises an N-type FET and wherein each of the first bottom FET and the second bottom FET comprises a P-type FET.

22. The method of claim 13, wherein each of the first top FET and the second top FET comprises a P-type FET and wherein each of the first bottom FET and the second bottom FET comprises an N-type FET.

23. The method of claim 13, wherein at least one of the first BM structure and the second BM structure comprise backside metal layer zero (BM0).

24. The method of claim 13, further comprising incorporating the semiconductor device into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
